(19) United States
(12) Patent Application Publication
(10) Pub. No.: US 2026/0118318 A1
(43) Pub. Date: Apr. 30, 2026

(54) CRACK PREDICTION METHOD AND APPARATUS, ELECTRONIC DEVICE, AND COMPUTER-READABLE STORAGE MEDIUM

(71) Applicants: DATANG NORTH CHINA ELECTRIC POWER TEST AND RESEARCH INSTITUTE, Beijing (CN); CHINA DATANG CORPORATION SCIENCE AND TECHNOLOGY GENERAL RESEARCH INSTITUTE, Beijing (CN)

(72) Inventors: Changfu LIU, Beijing (CN); Derui GUO, Beijing (CN); Hao ZHOU, Beijing (CN); Yanru LIU, Beijing (CN); Zhibo YANG, Beijing (CN); Ga TU, Beijing (CN); Kai GAO, Beijing (CN); Qingfeng WANG, Beijing (CN); Xin CHEN, Beijing (CN)

(73) Assignees: DATANG NORTH CHINA ELECTRIC POWER TEST AND RESEARCH INSTITUTE, Beijing (CN); CHINA DATANG CORPORATION SCIENCE AND TECHNOLOGY GENERAL RESEARCH INSTITUTE, Beijing (CN)

(21) Appl. No.: 19/232,530

(22) Filed: Jun. 9, 2025

Related U.S. Application Data
(63) Continuation of application No. PCT/CN2024/129547, filed on Nov. 4, 2024.

(30) Foreign Application Priority Data
Oct. 30, 2024 (CN) 202411528241.3

(51) Int. Cl. G01N 27/83; G01R 33/09

(52) U.S. Cl. CPC G01N 27/83; G01R 33/091

(57) ABSTRACT

The invention relates to the technical field of thermal power generation, and discloses a crack prediction method and apparatus, an electronic device and a computer-readable storage medium. The method includes: detecting a magnetic flux leakage at a to-be-detected welding joint; and predicting, based on the magnetic flux leakage at the to-be-detected welding joint, a tendency of the to-be-detected welding joint to have a crack. This allows for the prevention of cracking at the joint or for timely repair and preventive treatment at locations of potential crack, thereby improving operation safety of units.

### CROSS-REFERENCE TO RELATED APPLICATIONS

This application claims the benefit of priority to the Chinese Patent Application No. 2024115282413, filed with the China National Intellectual Property Administration on Oct. 30, 2024, and entitled “Crack Prediction Method and Apparatus, Electronic Device, and Computer-Readable Storage Medium”, which is incorporated by reference in its entirety.

### TECHNICAL FIELD

The present disclosure relates to the technical field of thermal power generation, and in particular, to a crack prediction method and apparatus, an electronic device, and a computer-readable storage medium.

### BACKGROUND

The coal-fired thermal power generating units are advancing towards the direction of ultra-supercritical high-parameter development, which places higher demands on the thermal strength and high-temperature oxidation resistance of boiler materials. 9Cr steels, such as P91 and P92, containing 9% to 12% Cr, are widely applied to 9Cr steel pipelines of high-parameter thermal power generating units due to their excellent thermal strength, favorable welding properties, and cost-effectiveness.

As the units operate for increasing duration, the pipes experience gradual aging and a decline in their microstructure and mechanical properties. However, for 9 Cr steel such as P91 and P92, a more severe concern is the formation of IV-type cracks in the fine-grained heat-affected zone. Once formed, these cracks can propagate rapidly and may even lead to a complete circumferential fracture of the welding joint, posing severe safety hazards to the units.

### SUMMARY

In view of the foregoing, embodiments of this application provide a crack prediction method and apparatus, an electronic device, and a computer-readable storage medium, to resolve the foregoing problems or at least partially resolve the foregoing problems.

In a first aspect, an embodiment of this application provides a crack prediction method, where the method includes: detecting a magnetic flux leakage at a to-be-detected welding joint; and predicting, based on the magnetic flux leakage at the to-be-detected welding joint, a tendency of the to-be-detected welding joint to have a crack.

In a second aspect, an embodiment of this application further provides a crack prediction apparatus, where the apparatus includes: a detection module, configured to detect a magnetic flux leakage at a to-be-detected welding joint; and a processing module, configured to predict, based on the magnetic flux leakage at the to-be-detected welding joint, a tendency of the to-be-detected welding joint to have a crack.

In a third aspect, an embodiment of this application further provides an electronic device, including: a processor; and a memory configured to store computer-executable instructions, where the executable instructions, when executed, cause the processor to perform the steps in the first aspect.

In a fourth aspect, an embodiment of this application further provides a computer-readable storage medium, where the computer-readable storage medium stores one or more programs which, when executed by an electronic device including a plurality of applications, enable the electronic device to perform the steps in the first aspect.

The at least one technical solution adopted in the embodiments of the present application can achieve the following beneficial effects. It facilitates the prediction of crack occurrence at a welding joint by detecting the magnetic flux leakage at the welding joint. This allows for the prevention of cracking at the joint or for timely repair and preventive treatment at locations of potential crack, thereby improving the operation safety of the units.

### BRIEF DESCRIPTION OF DRAWINGS

The drawings described herein are used to provide a further understanding of the present application and constitute a part of the present application. The illustrative embodiments of the present application and the description thereof are used to explain the present application, and do not constitute an improper limitation on the present application. In the drawings:

FIG. 1 is a schematic flowchart of a crack prediction method according to an embodiment of this application;

FIG. 2 is a structural diagram of a crack prediction apparatus according to an embodiment of this application; and

FIG. 3 is a schematic structural diagram of an electronic device according to an embodiment of this application.

### DETAILED DESCRIPTION OF THE EMBODIMENTS

To make the objectives, technical solutions, and advantages of this application clearer, the following clearly and completely describes the technical solutions of this application with reference to specific embodiments of this application and the accompanying drawings. Apparently, the described embodiments are only a part but not all of the embodiments of the present disclosure. All other embodiments obtained by any person of ordinary skill in the art based on the embodiments of this application without creative efforts shall fall within the protection scope of this application.

It should be noted that the terms “first”, “second”, and the like in the specification, claims, and drawings of this application are used to distinguish similar objects, and are not necessarily used to describe a specific order or sequence. It should be understood that such use may be interchanged where appropriate, so that the embodiments of the present disclosure described herein can be implemented in an order other than those illustrated or described herein. In addition, the term “include” and variations thereof are to be interpreted as open-ended term meaning “including but not limited to”.

As described in the BACKGROUND section, coal-fired thermal power generating units are advancing towards the direction of ultra-supercritical high-parameter development, which places higher demands on the thermal strength and high-temperature oxidation resistance of boiler materials. 9Cr steels, such as P91 and P92, containing 9% to 12% Cr, are widely applied to 9Cr steel pipelines of high-parameter thermal power generating units due to their excellent thermal strength, favorable welding properties, and cost-effectiveness.

As the units operate for increasing duration, the pipes experience gradual aging and a decline in their microstructure and mechanical properties. However, for 9 Cr steel such as P91 and P92, a more severe concern is the formation of IV-type cracks in the fine-grained heat-affected zone. Once formed, these cracks can propagate rapidly and may even lead to a complete circumferential fracture of the welding joint, posing severe safety hazards to the units.

The IV-type creep cracking process at the 9 Cr steel welding joint is a creep degradation process occurring in its fine-grained heat-affected zone. During the welding process, the carbides on the coarse austenite grain boundaries in the wood are not completely dissolved but instead precipitate on the grain boundaries of the fine-grained zone formed after welding. In the process of high temperature creep, the strengthening carbides in the fine-grained zone decrease while the carbides on the grain boundaries grow larger and form new coarse carbides, acting as nucleation sites for creep voids. This leads to a degradation of creep properties in the fine-grained zone. When creep voids on the grain boundaries enlarge, coalesce, and connect, grain boundary separation will occur. As the separated grain boundaries continuously increase, microcracks form on the austenite grain boundaries, eventually leading to macroscopic cracking. Essentially, the IV-type cracks are the accumulation and growth of creep voids under stress, with IV-type cracks first initiating in stress concentration regions. Furthermore, magnetic characteristics at the welding joint will vary with a change in the stress at the welding joint.

Therefore, the development trend of the IV-type cracks can be predicted by detecting the stress condition at the welding joint, providing technical support for safe and stable operation of the pipelines.

The present disclosure will be described in detail below through specific embodiments.

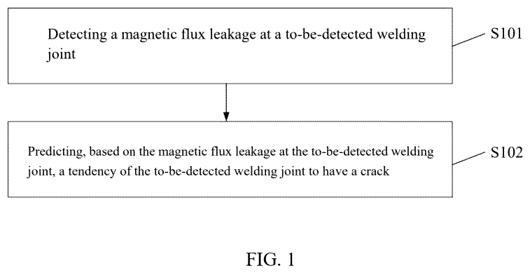

FIG. 1 shows a schematic flowchart of a crack prediction method according to an embodiment of this application. It can be seen from FIG. 1 that the method includes at least steps S101 to S102.

In step S101, a magnetic flux leakage at a to-be-detected welding joint is detected.

The to-be-detected welding joint is a 9Cr steel welding joint. Certainly, other welding joints applicable to the embodiments of this application are also included in the protection scope of this application.

In some embodiments, the magnetic flux leakage at the to-be-detected welding joint is detected by a magnetic flux leakage sensor, such as a Hall element, a giant magnetoresistance sensor, a coil sensor, or a magnetoelectric sensor.

The magnetic flux leakage includes a tangential magnetic flux leakage and a normal magnetic flux leakage. The tangential magnetic flux leakage refers to a magnetic flux leakage component parallel to the surface of the welding joint. After the joint is magnetized, a defect (such as a crack or void) that may exist will break the continuity of the magnetic flux line, causing the magnetic flux to leak along two sides of the defect thereby forming the tangential magnetic flux leakage. The intensity and distribution of the tangential magnetic flux leakage can reflect the size and shape of the defect and the extent to which the defect affects the magnetic flux line. The normal magnetic flux leakage refers to a magnetic flux leakage component perpendicular to the surface of the welding joint. In the presence of a defect, the magnetic flux will leak perpendicular to the surface of the joint, forming the normal magnetic flux leakage. The presence and variation of the normal magnetic flux leakage can be used to identify surface-breaking defects, such as cracks.

In step S102, a tendency of the to-be-detected welding joint to have a crack is predicted based on the magnetic flux leakage at the to-be-detected welding joint.

The crack is an IV-type crack. The tendency of the welding joint to have a crack indicates a situation that there are no cracks at the welding joint at present but instead the detected magnetic flux leakage suggests that cracks will form at some time in the future and also suggests the probability of such crack formation.

It can be seen from the method shown in FIG. 1 that the present application predicts whether cracks will form at the welding joint between pipelines by detecting the magnetic flux leakage at the joint. This aims to prevent crack formation or allow for timely maintenance or preventative treatment of areas likely to develop cracks, thereby enhancing the operational safety of the joint, thereby improving the safety of the operation of the joint.

In some embodiments of this application, step S102 involves detecting the magnetic flux leakage at the to-be-detected welding joint, which facilitates determination of the stress and its change trend which are in turn used for predicting the tendency for crack formation at that joint.

Specifically, a first association relationship between the magnetic flux leakage and the stress is determined in advance. The stress at the to-be-detected welding joint is determined by searching the first association relationship based on the magnetic flux leakage at the to-be-detected welding joint. Further, the change trend of the stress at the to-be-detected welding joint is determined based on the stress at the to-be-detected welding joint and the stress data at the to-be-detected welding joint determined previously. For example, the stress at the weld joint measured 10 Pa at 7:00, 11 Pa at 10:00, and 12 Pa at 13:00, and currently measures 13 Pa at 16:00. It can be seen that the stress increases by 1 Pa every 3 hours.

The first association relationship is determined as follows. The magnetic flux leakage sensor detects the magnetic flux leakage at a welding joint that has completed its standard heat treatment and is free of defects. The magnetic flux leakage sensor also detects the magnetic flux leakage at an in-service welding joint under various known stress conditions. Then the first association relationship between the magnetic flux leakage and stress is established through multiple sets of data correlating stress and leakage magnetic field.

In some embodiments of this application, the tendency for crack formation at the joint predicted based on the stress and the change trend of the stress is specifically determined based on a second association relationship. The second association relationship is a pre-established correspondence between different levels of stress and probability of crack formation. Specifically, crack formation behaviors at the welding joint under different levels of stress are observed, and the second association relationship between different levels of stress and crack formation is established by collecting multiple sets of data relating stress to crack details.

Specifically, whether the stress measured currently at the to-be-detected welding joint will result in cracks is determined by searching the second association relationship. If no crack is currently detected under this stress, the possibility of future crack formation is further predicted based on the change trend in stress and the second association relationship at the to-be-detected welding joint. For example, the stress increases by 1 Pa every 3 hours and currently measures 20 Pa, the second association relationship indicates that the welding joint may crack at 22 Pa, then it can be predicted that a crack may develop in approximately 6 hours. Further, the size (e.g., length and width) of the predicted crack at the to-be-detected welding joint may also be determined according to the second association relationship.

In the embodiments of this application, it is possible to determine whether a crack is likely to develop in the future as well as the estimated timing and size of the crack at a welding joint by predicting the tendency of crack formation at the welding joint. This can assist technical personnel in taking preventive measures, thereby ensuring the safe operation of the device.

In some embodiments of this application, when predicting the tendency of crack formation, the welding joint identified as having a potential crack formation is monitored in real time. The real-time magnetic flux leakage is compared with the previous magnetic flux leakage at the same welding joint, and/or the real-time magnetic flux leakage at the welding joint is compared with the neighboring magnetic flux leakage to determine whether a crack has already formed at the welding joint.

The welding joint is monitored in real time by an array magnetic flux leakage sensor.

Specifically, a significant difference (for example, greater than a preset error) between the real-time magnetic flux leakage and the previous magnetic flux leakage data indicates that a crack has formed at the welding joint, which results in the change in the magnetic flux leakage. Similarly, a significant difference (for example, greater than a preset error) between the real-time magnetic flux leakage and the neighboring magnetic flux leakage data indicates that a crack has formed at the welding joint.

In some other embodiments, it is determined, by using the real-time magnetic flux leakage, the first association relationship, and the second association relationship, whether the welding joint has a crack. Specifically, the stress corresponding to the real-time magnetic flux leakage is determined through the real-time magnetic flux leakage and the first association relationship, and whether the stress resulted in cracks is determined through the stress and the second association relationship.

In the embodiments of this application, whether a welding joint has a crack can be confirmed by detecting the magnetic flux leakage at the welding joint, so that a technician can carry out timely repairs to a welding joint where cracks are formed.

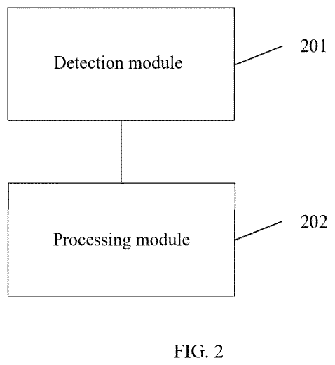

In some embodiments of this application, a crack prediction apparatus is provided, where the crack prediction apparatus corresponds to the crack prediction method in the foregoing embodiments. As shown in FIG. 2, the crack prediction apparatus includes a detection module 201 and a processing module 202 which are described in detail below.

The detection module 201 is configured to detect a magnetic flux leakage at a to-be-detected welding joint.

The processing module 202 is configured to predict, based on the magnetic flux leakage at the to-be-detected welding joint, a tendency of the to-be-detected welding joint to have a crack.

In some embodiments of the present disclosure, the processing module 202 of the above apparatus is specifically configured to detect a stress at the to-be-detected welding joint and a change trend of the stress based on the magnetic flux leakage at the to-be-detected welding joint; and predict the tendency of the to-be-detected welding joint to have a crack based on the stress at the to-be-detected welding joint and the change trend of the stress.

In some embodiments of this application, the processing module 202 of the above apparatus is specifically configured to determine a first association relationship between the magnetic flux leakage and the stress; determine, via the first association relationship, the stress at the to-be-detected welding joint based on the magnetic flux leakage at the to-be-detected welding joint; and determine the change trend of the a stress at the to-be-detected welding joint based on the stress at the to-be-detected welding joint and the stress data at the to-be-detected welding joint determined previously.

In some embodiments of the present application, the processing module 202 of the above apparatus is specifically configured to detect a magnetic flux leakage at a welding joint that has completed its standard heat treatment and is free of defects; detect the magnetic flux leakage at an in-service welding joint under various known stress conditions; and establish the first association relationship between the magnetic flux leakage and the stress based on the magnetic flux leakage at the welding joint that is free of defects and the magnetic flux leakage at the welding joint under various known stress conditions.

In some embodiments of this application, the processing module 202 of the foregoing apparatus is specifically configured to establish a second association relationship between different levels of stress and a probability of crack formation; and predict, through the second association relationship, the tendency of the to-be-detected welding joint to have a crack based on the stress at the to-be-detected welding joint and the change trend of the stress.

In some embodiments of the present disclosure, the processing module 202 of the foregoing apparatus is specifically configured to monitor, in real time, a flux leakage at a welding joint identified as having a potential crack formation; and compare the real-time magnetic flux leakage with the previous magnetic flux leakage at the same welding joint; and/or compare the real-time magnetic flux leakage at the welding joint with the neighboring magnetic flux leakage to determine whether a crack has already formed the welding joint.

In some embodiments of the present disclosure, the crack is an IV-type crack, and the to-be-detected welding joint is a 9 Cr steel welding joint.

It should be noted that the above crack prediction apparatus may implement the foregoing crack prediction method, and corresponding details are not repeated.

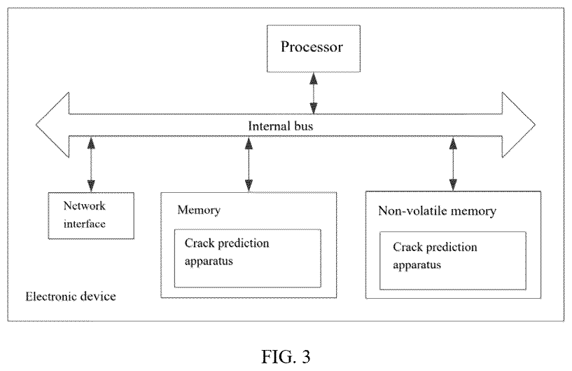

FIG. 3 is a schematic structural diagram of an electronic device according to an embodiment of this application. As shown in FIG. 3, at a hardware level, the electronic device includes a processor, and optionally further includes an internal bus, a network interface, and a storage. The storage may include a memory, for example, a high-speed random-access memory (RAM), or may further include a non-volatile memory, for example, at least one disk memory. Certainly, the electronic device may further include hardware required by other services.

The processor, the network interface, and the memory may be connected to each other through an internal bus, and the internal bus may be an Industry Standard Architecture (ISA) bus, a Peripheral Component Interconnect (PCI) bus, an Extended Industry Standard Architecture (EISA) bus, or the like. The bus may be an address bus, a data bus, a control bus, or the like. For ease of representation, only one bidirectional arrow is used to represent the bus in FIG. 3, but this does not mean that there is only one bus or one type of bus.

The memory is configured to store a program. Specifically, the program may include program code, and the program code includes a computer operation instruction. The memory may include a memory and a non-volatile memory, and provide instructions and data to the processor.

The processor reads the corresponding computer program from the non-volatile memory into the memory and then runs the computer program, forming the crack prediction apparatus on the logic level. The processor executes the program stored in the memory, and is specifically configured to perform the foregoing method.

The processor may be an integrated circuit chip, and has a signal processing capability. In practice, steps of the foregoing method may be implemented by an integrated logic circuit of hardware in the processor or an instruction in a form of software. The processor may be a general-purpose processor such as a central processing unit (CPU) or a network processor (NP), or may be a digital signal processor (DSP), an application-specific integrated circuit (ASIC), a field-programmable gate array (FPGA) or another programmable logic device, a discrete gate or transistor logic device, or a discrete hardware component. The processor may implement or perform the methods, steps, and logical block diagrams disclosed in the embodiments of this application. The general-purpose processor may be a microprocessor, any conventional processor or the like. The steps of the method disclosed in the embodiments of this application may be directly performed by a hardware decoding processor, or may be performed by a combination of hardware and software modules in a decoding processor. The software module may be located in a mature storage medium in the art, such as a random-access memory, a flash memory, a read-only memory, a programmable read-only memory, an electrically erasable programmable memory, or a register. The storage medium is located in the storage, and the processor reads information in the storage and performs the steps of the foregoing method in combination with hardware of the processor.

The electronic device may perform the crack prediction method provided in the embodiments of this application, and implement the function of the crack prediction apparatus in the embodiment shown in FIG. 2, and thus corresponding details are not repeated.

An embodiment of this application further provides a computer-readable storage medium, where the computer-readable storage medium stores one or more programs, and the one or more programs include instructions that, when executed by an electronic device including a plurality of applications, enable the electronic device to perform the crack prediction method provided in the embodiments of this application.

Any person skilled in the art should understand that the embodiments of this application may be provided as a method, a system, or a computer program product.

Therefore, this application may be implemented as purely hardware-based embodiments, purely software-based embodiments, or embodiments combining both software and hardware. Moreover, this application may also be implemented as a computer program product stored on one or more computer-readable storage media (including but not limited to a disk memory, a CD-ROM, an optical memory, and the like) including computer-readable program codes.

This application is described with reference to flowcharts and/or block diagrams of methods, apparatuses (systems), and computer program products according to embodiments of this application or a block diagram. It should be understood that each step and/or block in the flowcharts and/or block diagrams, as well as combinations of steps and/or blocks in the flowcharts and/or block diagrams, can be implemented by computer program instructions. These computer program instructions may be provided to a processor of a general-purpose computer, special purpose computer, embedded processor, or other programmable data processing device to produce a machine, such that the instructions executed by the processor of the computer or other programmable data processing device generate means for implementing the functions specified in one or more steps of the flowcharts and/or blocks of the block diagrams.

These computer program instructions may also be stored in a computer-readable memory capable of directing a computer or other programmable data processing device to function in a particular manner, such that the instructions stored in the computer readable memory produce an article of manufacture including an instruction device that implements functions specified in one or more steps of the flowcharts and/or one or more blocks in the block diagrams.

These computer program instructions may also be loaded onto a computer or other programmable data processing device such that a series of operational steps are performed on the computer or other programmable device to produce a computer-implemented process, such that the instructions executed on the computer or other programmable device provide steps for implementing the functions specified in one or more steps of the flowcharts and/or one or more blocks of the block diagrams.

In a typical configuration, a computing device includes one or more processors (CPU), input/output interfaces, network interfaces, and memories.

The memory may include a non-persistent memory, a random-access memory (RAM), and/or a non-volatile memory in a computer-readable medium, for example, a read-only memory (ROM) or a flash RAM. The memory is an example of a computer-readable medium.

The computer-readable medium includes persistent and non-persistent, movable and non-removable media that can store information in various manners. The information may be a computer-readable instruction, a data structure, a program module, or other data. Examples of computer storage media include, but are not limited to, a phase change memory (PRAM), a static random access memory (SRAM), a dynamic random access memory (DRAM), other types of random access memory (RAM), a read only memory (ROM), an electrically erasable programmable read only memory (EEPROM), a flash memory or other memory technology, a compact disc read only memory (CD-ROM), a digital versatile disk (DVD) or other optical storage, a magnetic cassette, a magnetic tape, a magnetic disk or other magnetic storage devices, or any other non-transitory medium, which can be used to store information accessible by a computing device. As defined herein, the computer-readable medium does not include transitory media, such as a modulated data signal and a carrier.

It should also be noted that the terms “comprising,” “including,” or any other variation thereof are intended to cover a non-exclusive inclusion, so that a process, method, commodity, or device that includes a series of elements includes not only those elements, but also other elements that are not explicitly listed, or elements inherent to such process, method, commodity, or device. An element defined by the phrase “comprising one . . . ” does not exclude the presence of additional identical elements in the process, method, commodity, or device that includes the element, unless otherwise specified.

Any person skilled in the art should understand that the embodiments of this application may be provided as a method, a system, or a computer program product. Therefore, the present disclosure may be implemented in the form of purely hardware embodiments, purely software embodiments or embodiments combining software and hardware. Moreover, this application may be embodied as a computer program product stored on one or more computer-readable storage media (including but not limited to a disk memory, a CD-ROM, an optical memory, and the like) including computer-readable program codes.

The foregoing descriptions are merely embodiments of this application, and are not intended to limit this application. For any person skilled in the art, the present disclosure may have various modifications and changes. Any modification, equivalent replacement, or improvement made without departing from the spirit and principle of this application shall fall within the scope of the claims of this application.

What is claimed is:

1. A crack prediction method, wherein the method comprises:
detecting a magnetic flux leakage at a to-be-detected welding joint; and
predicting, based on the magnetic flux leakage at the to-be-detected welding joint, a tendency of the to-be-detected welding joint to have a crack.

2. The method according to claim 1, wherein the predicting, based on the magnetic flux leakage at the to-be-detected welding joint, a tendency of the to-be-detected welding joint to have a crack comprises:
determining, based on the magnetic flux leakage at the to-be-detected welding joint, a stress at the to-be-detected welding joint and a change trend of the stress; and
predicting the tendency of the to-be-detected welding joint to have a crack based on the stress at the to-be-detected welding joint and the change trend of the stress.

3. The method according to claim 2, wherein the determining, based on the magnetic flux leakage at the to-be-detected welding joint, a stress at the to-be-detected welding joint and a change trend of the stress comprises:
establishing a first association relationship between the magnetic flux leakage and the stress;
determining the stress at the to-be-detected welding joint based on the magnetic flux leakage at the to-be-detected welding joint through the first association relationship; and
determining the change trend of the stress at the to-be-detected welding joint based on the stress at the to-be-detected welding joint and previous stress data at the to-be-detected welding joint.

4. The method according to claim 3, wherein the establishing a first association relationship between the magnetic flux leakage and the stress comprises:
detecting a magnetic flux leakage at a welding joint that has completed its heat treatment and is free of defects; and
detecting a magnetic flux leakage at an in-service welding joint under various stress conditions; and
establishing the first association relationship between the magnetic flux leakage and the stress based on the magnetic flux leakage at the welding joint that is free of defects and the magnetic flux leakage at the welding joint under various stress conditions.

5. The method according to claim 2, wherein the predicting the tendency of the to-be-detected welding joint to have a crack based on the stress at the to-be-detected welding joint and the change trend of the stress comprises:
establishing a second association relationship between different levels of stress and a probability of crack formation; and
predicting, through the second association relationship, the tendency of the to-be-detected welding joint to have a crack based on the stress at the to-be-detected welding joint and the change trend of the stress.

6. The method according to claim 1, wherein the method further comprises:
monitoring a real-time magnetic flux leakage at a welding joint identified as having a potential crack formation; and
comparing the real-time magnetic flux leakage with a previous magnetic flux leakage at the same welding joint, and/or comparing the real-time magnetic flux leakage at the welding joint with a neighboring magnetic flux leakage, to determine whether a crack has already formed at the welding joint.

7. The method according to a claim 1, wherein the crack is an IV-type crack, and the to-be-detected welding joint is a 9Cr steel welding joint.

8. A crack prediction apparatus, comprising:
a detection module, configured to detect a magnetic flux leakage at a to-be-detected welding joint; and
a processing module, configured to predict, based on the magnetic flux leakage at the to-be-detected welding joint, a tendency of the to-be-detected welding joint to have a crack.

9. An electronic device, comprising:
a processor; and
a memory configured to store computer-executable instructions, wherein the executable instructions, when executed, cause the processor to perform steps of the crack prediction method according to claim 1.

10. A computer-readable storage medium storing one or more programs, wherein the one or more programs, when executed by an electronic device including a plurality of applications, cause the electronic device to perform steps of the crack prediction method according to claim 1.
